(19) United States
(12) Patent Application Publication
(10) Pub. No.: US 2026/0075913 A1
(43) Pub. Date: Mar. 12, 2026

(54) SEMICONDUCTOR DEVICE AND METHOD OF MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yuki SHIBUTANI, Hakusan Ishikawa (JP)

(21) Appl. No.: 19/070,422

(22) Filed: Mar. 4, 2025

(30) Foreign Application Priority Data
Sep. 9, 2024 (JP) 2024-155190

(51) Int. Cl. H10D 64/23; H10D 30/66; H10D 64/00; H10D 64/27; H10D 64/66; H10D 84/01; H10D 84/83

(52) U.S. Cl. CPC H10D 64/2527; H10D 30/668; H10D 84/016; H10D 84/839; H10D 64/117; H10D 64/513; H10D 64/661

(57) ABSTRACT

According to one embodiment, a semiconductor device includes first and second electrodes, control electrodes between the first electrode and the second electrode, a semiconductor layer between the first electrode and the second electrode in ohmic contact with the first electrode, insulating portions between the semiconductor layer and each control electrode, third electrodes between control electrodes, each third electrode being sandwiched between adjacent insulating portions, and a second semiconductor region between adjacent third electrodes. The second semiconductor region being in Schottky contact with the third electrodes and having a width along the third direction that is greater than its width along the second direction.

### CROSS-REFERENCE TO RELATED APPLICATION(S)

This application is based upon and claims the benefit of priority from Japanese Patent Application No. 2024-155190, filed Sep. 9, 2024, the entire contents of which are incorporated herein by reference.

### FIELD

Embodiments described herein relate generally to a semiconductor device and a method for manufacturing a semiconductor device.

### BACKGROUND

A semiconductor device is known which switches between an ON state and an OFF state by controlling the height of a Schottky barrier using a voltage applied to a gate electrode.

### BRIEF DESCRIPTION OF THE DRAWINGS

FIG. 1 is a schematic plan view illustrating aspects of a semiconductor device according to an embodiment of the present disclosure.

FIG. 2A is a schematic cross-sectional view along line A-A of FIG. 1.

FIG. 2B is a schematic cross-sectional view along line B-B of FIG. 1.

FIG. 3 is a schematic perspective view illustrating aspects of a semiconductor device centering on region D in FIG. 1.

FIG. 4A is a view of region D of FIG. 1 in the off state.

FIG. 4B is a view of region D in FIG. 1 in the ON state.

FIG. 5 depicts aspects related to parasitic capacitance in a semiconductor device according to an embodiment of the present disclosure.

FIG. 6 depicts aspects related to parasitic capacitance of a semiconductor device according to a modification example.

FIG. 7 is a schematic plan view showing the configuration of a semiconductor device of a comparative example.

FIG. 8 is a schematic cross-sectional view showing the structure of the comparative example semiconductor device along line D-D in FIG. 7.

FIGS. 9A to 9D are views illustrating aspects of a method of manufacturing a semiconductor integrated circuit device according to an embodiment of the present disclosure.

### DETAILED DESCRIPTION

Embodiments provide a semiconductor device capable of reducing on-resistance and a method for manufacturing the same.

In general, according to one embodiment, a semiconductor device, includes a first electrode, a second electrode separated from the first electrode in a first direction, a plurality of control electrodes between the first electrode and the second electrode, each control electrode extending in a second direction intersecting the first direction and spaced from each other in a third direction intersecting the first and second directions, a semiconductor layer between the first electrode and the second electrode and having a first semiconductor region in ohmic contact with the first electrode, a plurality of insulating portions in the semiconductor layer between the semiconductor layer and each control electrode, a plurality of third electrodes between adjacent control electrodes of the plurality of control electrode in the third direction and spaced from each other third electrode in the second direction, each third electrode being sandwiched between adjacent insulating portions in the third direction and electrically connected to the second electrode; and a second semiconductor region on the first semiconductor region in the semiconductor layer, the second semiconductor region having an impurity concentration higher than that of the first semiconductor region and being between adjacent third electrodes of the plurality of third electrodes in the second direction, the second semiconductor region being in Schottky contact with the adjacent third electrodes and having a width along the third direction that is greater than its width along the second direction.

In general, according to another embodiment, a method of manufacturing a semiconductor device includes forming control electrodes arranged in a third direction intersecting the first direction and the second direction in a plurality of insulating portions provided in a semiconductor layer, forming a plurality of trench contacts in the semiconductor layer between the plurality of control electrodes arranged in the second direction, removing portions of the semiconductor layer until side walls of the plurality of trench contacts reach the adjacent insulating portions; and forming a plurality of third electrodes in the plurality of trench contacts, the third electrodes being in Schottky contact with the semiconductor layer.

Hereinafter, certain example embodiments of the present disclosure will be described with reference to the drawings. These example embodiments do not limit the present disclosure. The drawings are schematic or conceptual, and as such the depiction of dimensions, relative dimensions, and the like of elements or components is not necessarily the same as in an actual device or implementation. In the specification and the drawings, the same reference symbols are given to the same elements and the detailed description of a previously described element may be appropriately omitted from description of subsequent drawings and the like.

For convenience of description, an XYZ orthogonal coordinate system is adopted for the figures. In general, the Z-axis direction is a stacking direction (layer thickness direction) of the depicted semiconductor device. The Y-axis direction is one of the planar directions in the semiconductor device, and more specifically, corresponds to a direction in which semiconductor elements are arranged. In the Z-axis direction, the source electrode side is also referred to as “upper” side, and the drain electrode side is referred to as “lower” side. However, this convention is for descriptive convenience and is independent of the direction of gravity.

In the following description, the expressions n⁺, n, n⁻, p⁺, p, and p⁻ may be used to represent the relative level of the impurity concentration by conductivity type. That is, n⁺ indicates that the n-type impurity concentration is relatively higher than n, and n⁻ indicates that the n-type impurity concentration is relatively lower than n. Further, p⁺ indicates that the p-type impurity concentration is relatively higher than p, and p⁺ indicates that the p-type impurity concentration is relatively lower than p. These expressions represent net impurity concentrations after compensation (offsetting) by impurity type when both the p-type impurity and the n-type impurity are contained in the respective regions. In this specification, the n-type, the n⁺-type, and the n⁻type are also each referred to as a first conductivity type. In this specification, the p-type, the p⁺-type, and the p⁻ type are also each referred to as a second conductivity type. The n-type and the p-type may be reversed in the described examples and other embodiments may thereby be provided.

The impurity concentration of a semiconductor region can be measured by, for example, secondary ion mass spectrometry (SIMS). The relative level of impurity concentration can also be determined from the level of the carrier concentration obtained by scanning capacitance microscopy (SCM), for example.

The dimensions such as the width of the diffusion region can be measured by, for example, analysis of the surface and/or the cross section by a transmission electron microscope (TEM), energy dispersive X-ray spectroscopy (EDX), or a scanning electron microscope (SEM).

The composition of a conductive portion or the like can be analyzed by energy dispersive X-ray spectroscopy or the like.

### Embodiment of the Present Disclosure

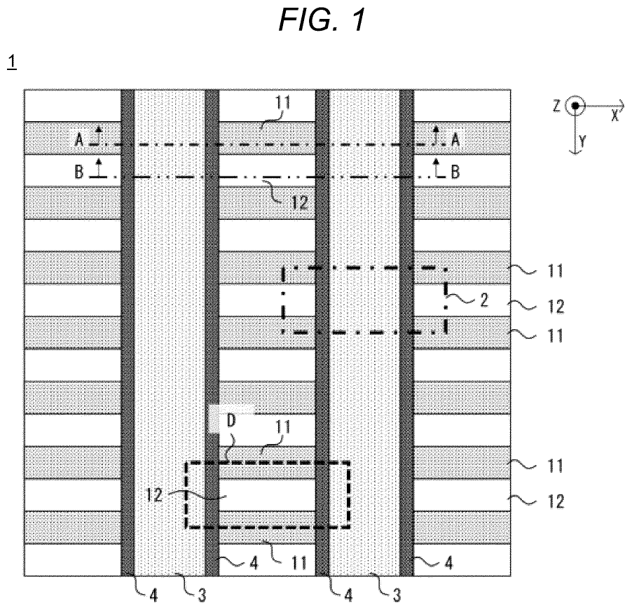

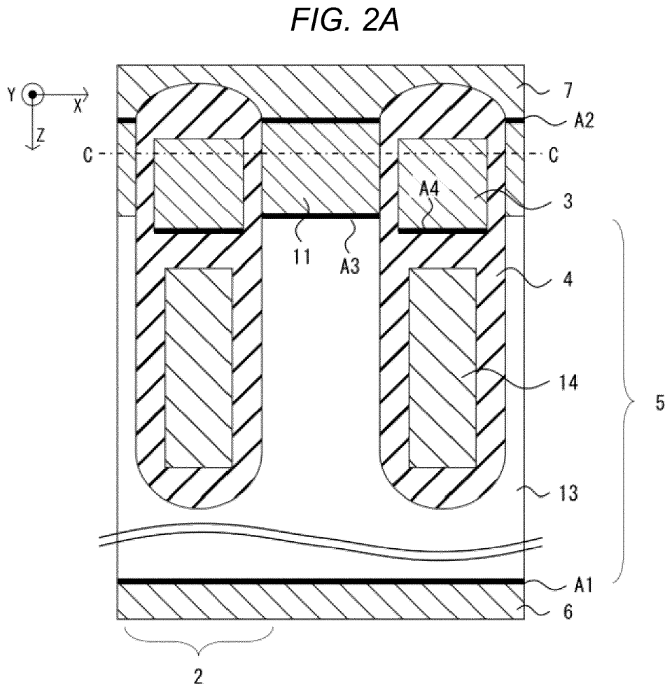

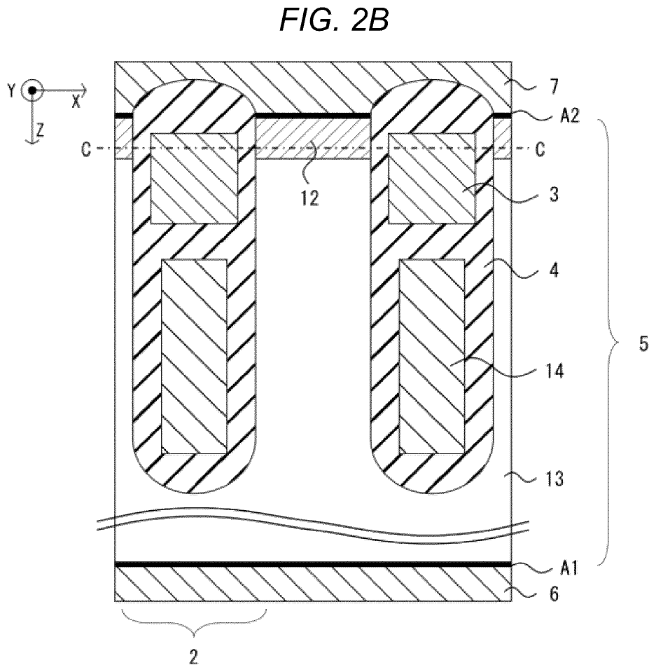

A semiconductor device 1 according to an embodiment of the present disclosure will be described with reference to FIGS. 1, 2A, and 2B. FIG. 1 is a schematic plan view illustrating a semiconductor device 1. The horizontal direction and the vertical direction of FIG. 1 correspond to the X-axis direction (third direction) and the Y-axis direction (second direction), respectively. The depth direction of FIG. 1 corresponds to the Z-axis direction (first direction). The plan view of FIG. 1 corresponds to a plane at the C-C line of FIG. 2A and FIG. 2B.

FIG. 2A is a first schematic cross-sectional view along line A-A of FIG. 1, and FIG. 2B is a second schematic cross-sectional view along line B-B of FIG. 1. FIG. 2A shows a cross section of the Schottky electrode 11, and FIG. 2B shows a cross section of the diffusion region 12. The horizontal direction and the vertical direction of FIG. 2A and FIG. 2B correspond to the X-axis direction and the Z-axis direction, respectively. In FIG. 2A and FIG. 2B, the depicted semiconductor element 2 is a MOSFET having field plate (FP) electrodes, that is, a FPMOS.

The semiconductor device 1 shown in FIGS. 1, 2A and 2B includes control electrodes 3, insulating portions 4, a semiconducting layer 5, electrodes 6 (first electrodes), electrodes 7 (second electrodes), Schottky electrodes 11 (third electrodes), diffusion regions 12 (second semiconducting regions), semiconducting regions 13 (first semiconducting regions), and conductive portions 14. The semiconductor device 1 includes a plurality of semiconductor elements 2.

Each semiconductor element 2 is a vertical transistor in which a current flows in the Z-axis direction. More specifically, the semiconductor element 2 is a vertical metal oxide silicon field effect transistor (MOSFET) that switches between an ON state and an OFF state when the potential of the control electrode 3 is controlled to change the height of a Schottky barrier. In the example of FIG. 1, semiconductor elements 2 are arranged along the X-axis direction and the Y-axis direction.

The control electrode 3 extends in the Y-axis direction. In the example of FIG. 1, a plurality of control electrodes 3 are arranged spaced from each other in the X-axis direction. As shown in FIG. 2A, the control electrodes 3 are disposed to face the electrodes 7 in the Z-axis direction. The control electrode 3 comprise, for example, polysilicon containing a p-type or n-type impurity. The control electrode 3 functions as a gate electrode of the MOSFET (semiconductor element 2) and controls a current flowing between the electrode 6 and the electrode 7.

The insulating portion 4 is arranged to surround each control electrode 3. As shown in FIG. 1, the insulating portion 4 insulates the control electrode 3 from the Schottky electrode 11. The insulating portion 4 also insulates the control electrode 3 from the diffusion region 12. The insulating portion 4 is, for example, a silicon oxide film (SiO₂).

As shown in FIG. 1, the Schottky electrode 11 is sandwiched between adjacent insulating portions 4 in the X-axis direction. A plurality of Schottky electrodes 11 are arranged along the Y-axis direction. More specifically, in the example of FIG. 1, a plurality of Schottky electrodes 11 are arranged along the Y-axis direction in a region between two control electrodes 3.

The diffusion region 12 is sandwiched between two Schottky electrodes 11 (a first Schottky electrode 11 and a second Schottky electrode 11) in the Y-axis direction. As shown in FIG. 1, the Schottky electrodes 11 and the diffusion regions 12 are alternately arranged with each other along the Y-axis direction between the two control electrodes 3. The diffusion region 12 is in contact with the two Schottky electrodes 11 and also with the electrodes 7 in the Z-axis direction as shown in FIG. 2B.

Note that the Schottky electrode 11 and the diffusion region 12 are not limited to being disposed between the insulating portions 4, and may be disposed between the control electrode 3 and an element isolation film or a protective film that isolates the semiconductor element 2 from other components (for example, another transistor, diode, or wiring layer controlled independently of the semiconductor device 1).

The semiconductor layer 5 is an n-type semiconductor region. The semiconductor layer 5 may be an epitaxial layer, a semiconductor substrate, or a semiconductor substrate with an epitaxial layer disposed thereon. In the present example, the semiconductor layer 5 is made of silicon (Si).

As shown in FIG. 2B, the semiconductor layer 5 includes a diffusion region 12 and a semiconductor region 13 which are electrically connected to each other. A semiconductor region having a higher n-type impurity concentration than the semiconductor region 13 may be provided between the semiconductor region 13 and the electrode 6 in some examples.

The diffusion region 12 is provided on the semiconductor region 13. The diffusion region 12 is an n-type semiconductor region having a higher impurity concentration than the semiconductor region 13. The n-type impurity concentration of the semiconductor region 13 is, for example, not less than 1×10¹⁵ cm⁻³ and not more than 2×10¹⁸ cm⁻³. In contrast, the n-type impurity concentration of the diffusion region 12 is, for example, 1×10¹⁸ cm⁻³ or more and 2×10²² cm⁻³ or less. For example, arsenic (As), phosphorus (P), antimony (Sb), or the like is implanted as an n-type impurity into the diffusion region 12.

The electrodes 6 are disposed on the first surface A1 side of the layer 5. The electrode 6 is a plate-like electrode and extends in the X-axis direction and the Y-axis direction. The electrode 6 is electrically connected to the semiconductor layer 5. The electrode 6 is in ohmic contact with the semiconductor layer 5. The electrode 6 is made of, for example, copper (Cu), titanium (Ti), tungsten (W), aluminum (Al), or the like. The electrode 6 functions as a drain electrode of the MOSFET.

The electrode 7 is separated from the electrode 6 in the Z-axis direction. The electrode 7 is a plate-like electrode and extends in the X-axis direction and the Y-axis direction. The electrodes 7 are disposed on the A2 side of the second surface side of the semiconductor layer 5 and electrically connected to the semiconductor layer 5. The electrodes 7 are electrically connected to the Schottky electrodes 11 as shown in FIG. 2A.

The Schottky electrodes 11 extend from an electrode 7 toward the first surface A1 side between adjacent insulating portions 4. Each Schottky electrode 11 is disposed to face a control electrode 3 in the X-axis direction. The Schottky electrode 11 is in Schottky contact with the diffusion region 12, and thus forms a Schottky barrier at the interface with the diffusion region 12. For example, a metal having a work function higher than that of the electrode 7 is used for the Schottky electrode 11.

The Schottky electrode 11 comprises, for example, at least one of Ti, W, Mo, Ta, Zr, Al, Sn, V, Re, Os, Ir, Pt, Pd, Rh, Ru, Nb, Sr, Co, and Hf. For example, the Schottky electrode 11 comprises platinum (Pt). The electrode 7 comprises, for example, at least one of Al, Cu, Mo, W, Ta, Co, Ru, Ti, and Pt. For example, the electrode 7 comprises tungsten (W).

Note that, in some examples, the Schottky electrode 11 and the electrode 7 may be made of or comprise the same metal. When the Schottky electrode 11 and the electrode 7 are made of the same metal, the Schottky electrode 11 and the electrode 7 may be formed integrally with one another.

It is desirable that the Schottky electrode 11 is embedded at a position (level) shallower than the control electrode 3 in the depth direction (Z-axis direction) of the semiconductor layer 5 or at substantially the same position (level). In particular, the lower end surfaces A3 of the Schottky electrodes 11 are preferably arranged at positions higher than or substantially equal to the lower end surfaces A4 of the control electrodes 3 in the depth direction. Thus, the lower end surface of a depletion layer (depletion layer 31, see FIG. 5) formed in the diffusion region 12 is formed above the lower end surface A3 of the Schottky electrodes 11, or more preferably, at substantially the same position (level). As a result, the parasitic capacitance (parasitic capacitor 41, see FIG. 5) between the gate and the drain can be further reduced.

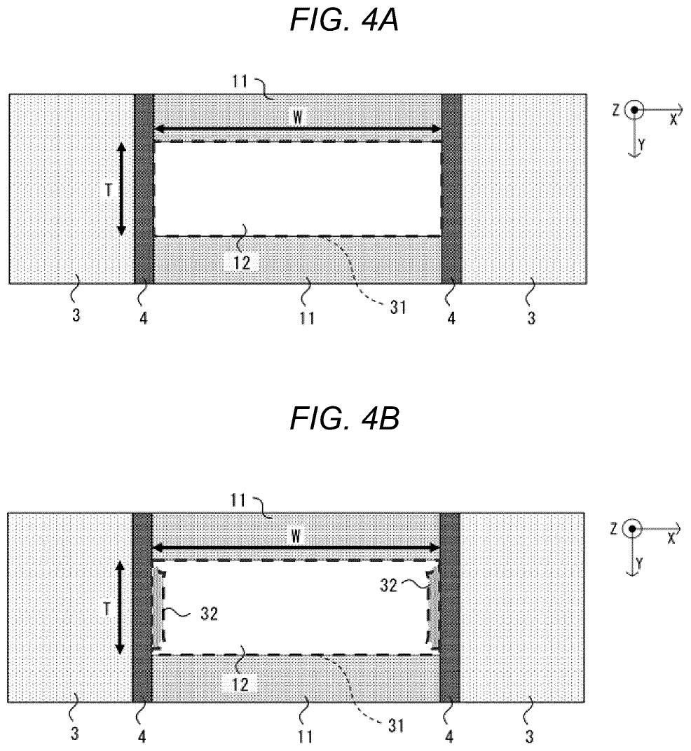

In the present specification, a state in which a predetermined voltage is applied to the control electrode 3 and a current flows between the electrode 6 and the electrode 7 is referred to as an ON state of the semiconductor element 2. A state in which current less than that of the ON state flows between the electrode 6 and the electrode 7 or no current flows between the electrode 6 and the electrode 7 is referred to as an OFF state of the semiconductor element 2. When the semiconductor element 2 is in an ON state, a channel (channel 32, see FIG. 4B) through which a current flows between the electrode 6 and the electrode 7 is formed in the diffusion region 12.

The threshold voltage of the semiconductor element 2 can be increased by increasing the Schottky barrier height at the interface between the Schottky electrode 11 and the diffusion region 12. Thus, the semiconductor element 2 can be configured as a normally-off MOSFET.

On the other hand, the source contact resistance between the electrode 7 and the diffusion region 12 is preferably low. By reducing the source contact resistance, the overall on-resistance of the semiconductor element 2 can be reduced, and the switching speed of the semiconductor element 2 can be increased, and the turn-on loss and the turn-off loss can be suppressed.

As shown in the FIG. 2A, the conductive portions 14 are provided below the control electrodes 3 but also inside the insulating portion 4 and function as field plate electrodes. Each conductive portion 14 is electrically connected to the electrode 7. The conductive portion 14 comprises, for example, polysilicon containing p-type or n-type impurities. By providing the conductive portion 14, when the semiconductor device 1 is in an off state, a depletion layer extends from the conductive portion 14 to the drift region around the conductive portion 14 due to a reverse voltage being applied between the drain electrode and the source electrode. This depletion layer can be connected to the depletion layer of an adjacent conductive portion 14. The withstand voltage (breakdown voltage) of the semiconductor device 1 can thus be improved.

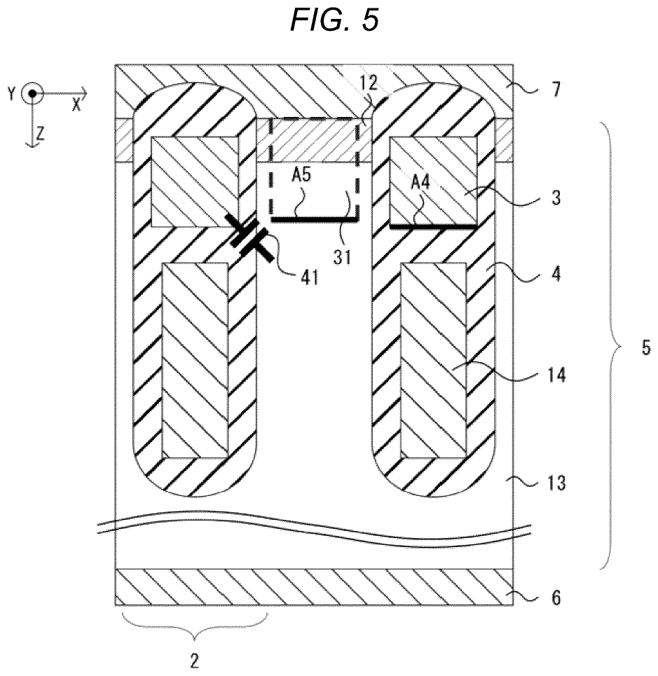

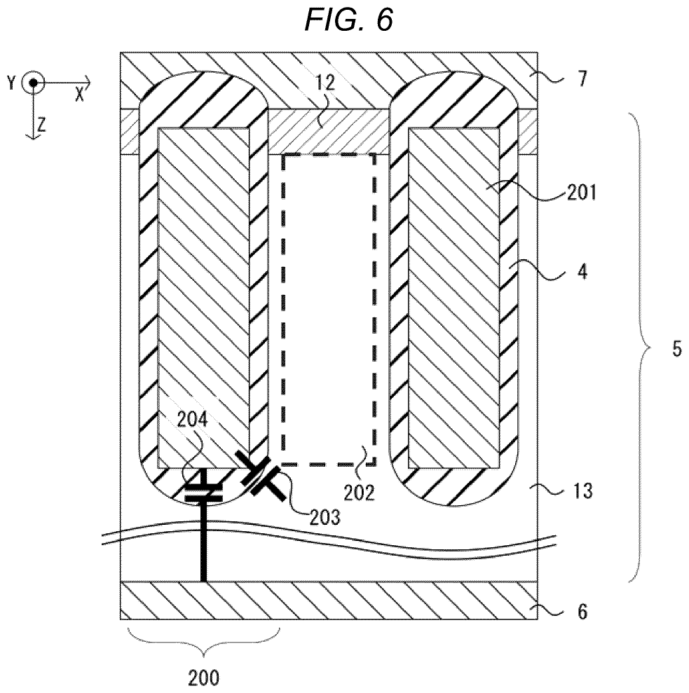

The semiconductor element 2 in some examples may have a configuration in which the conductive portion 14 is omitted. That is, the semiconductor element 2 may have a trench MOS structure according to a modification example(see, e.g., FIG. 6).

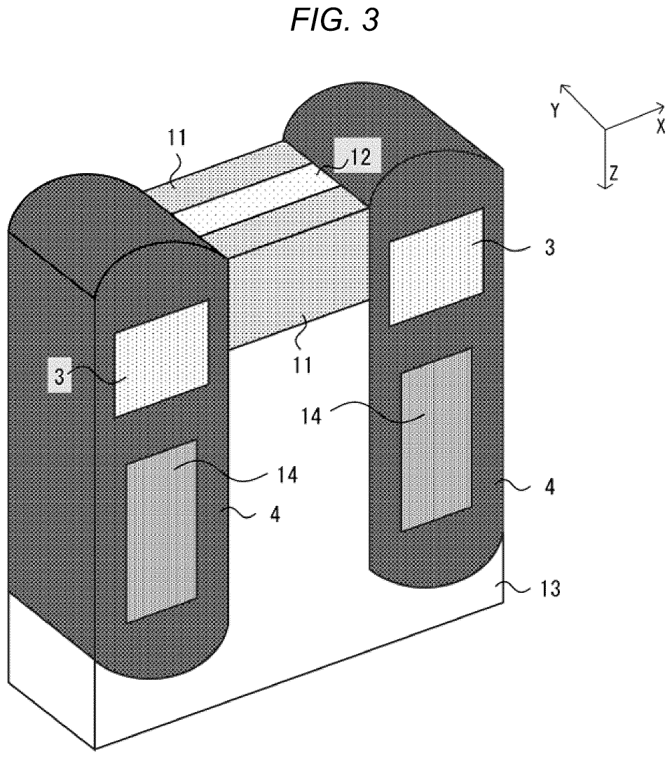

FIG. 3 is a schematic perspective view illustrating a region D of the semiconductor device 1 in FIG. 1. FIG. 3 illustrates two control electrodes 3, two insulating portions 4, two Schottky electrodes 11, a diffusion region 12, a semiconductor region 13, and two conductive portions 14.

Aspects of a semiconductor element 2 will be described with reference to FIGS. 4A and 4B. FIGS. 4A and 4B are views of the region D in FIG. 1. In FIG. 4A, the off state of the semiconductor element 2 is shown. In FIG. 4B, the semiconductor element 2 is shown in an ON state.

In FIGS. 4A and 4B, two control electrodes 3, two insulating portions 4, two Schottky electrodes 11, and a diffusion region 12 are shown. The two control electrodes 3 are arranged to face each other in the X-axis direction. The two Schottky electrodes 11 are arranged to face each other in the Y-axis direction. The two insulating portions 4 insulate the control electrodes 3 from the Schottky electrodes 11 and the diffusion region 12. The diffusion region 12 is disposed between the adjacent control electrodes 3 and between the adjacent Schottky electrodes 11.

A depletion layer 31 forms at the interface between the diffusion region 12 and each Schottky electrode 11. The depletion layer 31 is a region in which the amount of charge is smaller than that in the other regions of the diffusion region 12 or in which no charge exists.

As shown in FIG. 4A, when the semiconductor element 2 is in the off state, the depletion layer 31 is formed on substantially the entire outer peripheral surface of the diffusion region 12 along the X-axis direction and the Y-axis direction.

The depletion layer 31 can be formed by, for example, joining two depletion layers formed at the interfaces of the diffusion region 12 with the Schottky electrodes 11. Specifically, a first depletion layer is formed at an interface between diffusion region 12 and one of two Schottky electrodes 11 (hereinafter referred to as first Schottky electrode 11). A second depletion layer is formed at the interface between the diffusion region 12 and the other of the two Schottky electrodes 11 (hereinafter referred to as a second Schottky electrode 11). The depletion layer 31 is thus formed by a joining or combining of the first depletion layer and the second depletion layer.

In FIG. 4B, a voltage is applied to the control electrodes 3, and the semiconductor element 2 switches to an ON state. When the semiconductor element 2 switches to the ON state, the depletion layer 31 is reduced (recedes) in the X-axis direction from the interface of the insulating portion 4 and the diffusion region 12. As a result, as shown in the FIG. 4B, a channel 32 (conductive region) is formed in the diffusion region 12. In this example, the channel 32 does not extend over the entire outer peripheral surface of the diffusion region 12 in the X-axis direction. That is, a channel 32 is formed at the interfaces between the insulating portions 4 and the diffusion region 12.

In the present description, the distance (dimension) from the interface of the diffusion region 12 and the first Schottky electrode 11 to the interface of the diffusion region 12 and the second Schottky electrode 11 (corresponding to the width of the diffusion region 12 along the Y-axis direction) is referred to as the thickness T of the diffusion region 12. The distance (dimension) from the interface of the diffusion region 12 and a first insulating portion 4 to the interface of the diffusion region 12 and a second insulating portion 4 (corresponding to the width of the diffusion region 12 along the X-axis direction) is referred to as the width W of the diffusion region 12. The width W may also be referred to as a width of mesa or a pitch of the semiconductor element 2.

In the example of FIGS. 4A and 4B, the thickness T is less than the width W. The thickness T may be less than or equal to half the width W in some examples. The thickness T may be, for example, 50 nm to 100 nm. The width W may be, for example, 100 nm to 200 nm. The numerical ranges for the thickness T and the width W are one measure for individually forming the channel 32 at the interface between the insulating portion 4 and the diffusion region 12.

As shown in FIG. 4B, in the diffusion region 12 in the ON state, the first boundary surface where the Schottky barrier is formed (that is, the interface between the diffusion region 12 and the Schottky electrodes 11) and the second boundary surface where the channel 32 is formed (that is, the interface between the diffusion region 12 and the insulating portion 4) are not opposite each other. In the semiconductor element 2, a wider channel can be formed at the second boundary surface when a voltage is applied to the control electrode 3, as compared to a structure in which the first boundary surface and the second boundary surface face each other. This arrangement as described for this embodiment can provide a reduced on-resistance for the semiconductor element 2.

In the ON state, the channel 32 is locally formed at the interface between the insulating portion 4 and the diffusion region 12, but does not spread over the entire surface of the diffusion region 12 in the X-axis direction. Therefore, the semiconductor element 2 can switch to an OFF state at high speed.

The thickness T of the diffusion region 12 is not limited to the above described dimensions, and may be thinned or thickened to the extent that the first depletion layer formed at the interface between the diffusion region 12 and the first Schottky electrode 11 will be coupled to the second depletion layer formed at the interface between the diffusion region 12 and the second Schottky electrode 11. The width W may be set as appropriate such that the dimension is sufficient for the channel 32 not to spread over the entire surface of the diffusion region 12 in the X-axis direction when the semiconductor element 2 is in the ON state.

The thickness T and the width W may be adjusted in accordance with such things as the materials selected for the Schottky electrode 11 and the diffusion region 12, the type or concentration of the impurity implanted into the diffusion region 12, the voltage to be applied to the control electrode 3 for the ON state, or the design temperature or expected operating conditions of the semiconductor element 2.

The thickness T and the width W of the semiconductor element 2 may be adjusted within the range in which the channel 32 will be locally formed at the interface between the diffusion region 12 and the insulating portion 4. By reducing the width W of the semiconductor element 2, the element pitch can be reduced (pitch shrink), and the semiconductor device 1 can be miniaturized. Further, the on-resistance can be reduced by increasing the density of the drift current.

In the present embodiment, the diffusion region 12 is in contact with both the first Schottky electrode 11 and the second Schottky electrode 11. This can increase the overall contact area between the Schottky electrodes 11 and the diffusion region 12 as compared with the configuration in which the diffusion region 12 is in contact with only one Schottky electrode, and thus can reduce the source contact resistance. Further, as the contact area increases, the degree of freedom with respect to the thickness T is improved, and the thickness T can be increased.

FIG. 5 is a view illustrating aspects related to reducing parasitic capacitance of the semiconductor element 2 according to an embodiment of the present disclosure. FIG. 5 shows a parasitic capacitor 41 (representing inherent parasitic capacitance) formed between the control electrode 3 and the electrode 6. The parasitic capacitor 41 forms between the control electrode 3 and the electrode 6 across the semiconductor layer 5 facing the control electrode 3 in the X-axis direction.

The parasitic capacitor 41 represents a gate-drain capacitance (Cgd). The parasitic capacitor 41 forms a feedback capacitance (Crss). When the parasitic capacitor 41 is large, the rise and fall of the drain-source voltage of the semiconductor element 2 are delayed, and the switching speed of the semiconductor element 2 is reduced.

In the semiconductor element 2, a depletion layer 31 extending in the X-axis direction is formed by the Schottky electrode 11. This can reduce the capacitance of the parasitic capacitor 41.

In the semiconductor element 2, in the OFF state, the depletion layer 31 is formed on substantially the entire surface of the diffusion region 12 along the X-axis direction (that is, from one insulating portion 4 to the other insulating portion 4), and thus the capacitance reducing effect of the parasitic capacitor 41 will be larger than that of a structure in which the depletion layer is formed only in a part of the diffusion region 12.

The portion of the depletion layer 31 disposed at the same height as the control electrode 3 contributes a larger effect in reducing the parasitic capacitance. Therefore, it is desirable that the depletion layer 31 be formed at substantially the same height as the lower end of the control electrode 3. Alternatively, the lower end of the depletion layer 31 may be formed at a position higher than the lower end of the control electrode 3. In order to form the depletion layer 31 as described above, it is desirable that the Schottky electrodes 11 are embedded at positions lower than the control electrodes 3 in the depth direction (Z-axis direction) or at least at substantially the same levels as the control electrodes 3, as shown in FIG. 2B.

### Modification

FIG. 6 is a view illustrating a parasitic capacitance of a semiconductor element 200 according to a modification. As shown in FIG. 6, the semiconductor element 200 is different from the semiconductor element 2 in that the semiconductor element 200 does not have a conductive portion 14 included therein. The semiconductor element 200 has a trench MOS structure in which a control electrode 201 is embedded in a trench of a semiconductor layer. In the semiconductor element 200, a depletion layer 202 is formed by a Schottky electrode 11 or the like.

In the semiconductor element 200, a parasitic capacitor 203 will form between the control electrode 201 and the electrode 6 via the semiconductor layer 5 facing the control electrode 201 in the X-axis direction. In the semiconductor element 200, a parasitic capacitor 204 also forms between the control electrode 201 and the electrode 6 via the semiconductor layer 5 facing the control electrode 201 in the Z-axis direction. The parasitic capacitors 203 and 204 represent gate-drain capacitances Cgd constituting the feedback capacitance Crss.

The depletion layer 202 is not formed in the vicinity of the parasitic capacitor 204, and thus the effect of reducing the parasitic capacitance by the depletion layer 202 cannot be obtained.

In contrast to the semiconductor element 200 of FIG. 6, in the semiconductor element 2 of FIG. 5, a conductive portion 14 is disposed between the control electrode 3 and the semiconductor layer 5 facing to the control electrode 3 in the Z-axis direction. Therefore, in the semiconductor element 2 of FIG. 5, a parasitic capacitance corresponding to the parasitic capacitor 204 is not formed. Therefore, the semiconductor element 2 can have a reduced parasitic capacitance as compared to the semiconductor element 200 according to the modification.

Next, a comparative example will be described to highlight certain aspects of an embodiment.

### Comparative Example

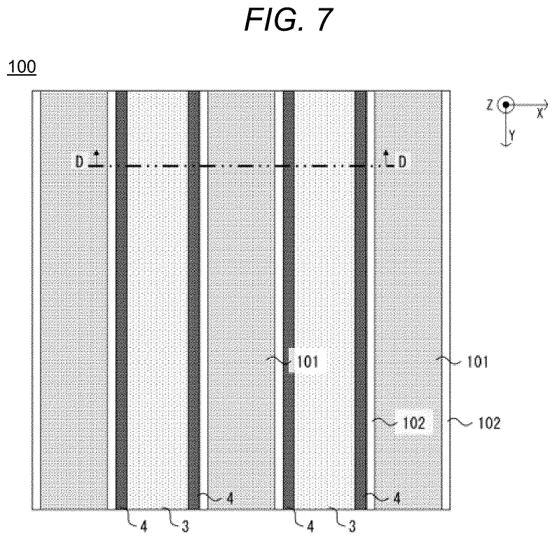

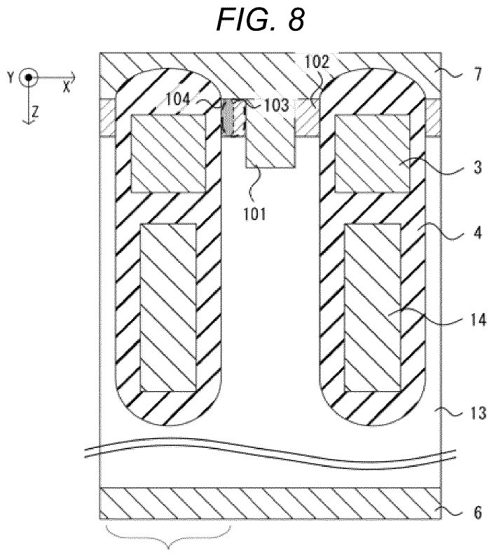

FIG. 7 is a schematic plan view showing the configuration of a semiconductor device 100 according to the comparative example. As shown in FIG. 7, the semiconductor device 100 is different from the semiconductor device 1 in that only one Schottky electrode 101 is disposed between the adjacent control electrodes 3. That is, the Schottky electrode 101 extends continuously along the Y-axis direction. In FIG. 7, a diffusion region 102 in which a channel 104 (see FIG. 8) is formed in the ON state is between the Schottky electrode 101 and the insulating portion 4.

FIG. 8 is a schematic cross-sectional view showing a configuration of the semiconductor device 100. FIG. 8 shows a cross section taken along line D-D of FIG. 7. FIG. 8 shows a depletion layer 103 formed in the diffusion region 102 and a channel 104 formed when a predetermined voltage is applied to the control electrode 3 to switch to an ON state.

As shown in FIG. 8, a depletion layer 103 and a channel 104 in the comparative example are formed at boundary surfaces facing each other. In particular, in the semiconductor device 100, when the Schottky barrier is increased to reduce the leakage current, the channel 104 will be less likely to be formed, which affects the resistance of the channel 104. Therefore, it is difficult to achieve both an improvement in the Schottky barrier height and a reduction in the on-resistance. In addition, when the width (dimension in the X-axis direction) of the diffusion region 102 is narrowed, the source contact resistance increases, and thus it is difficult to reduce the pitch in the semiconductor device 100.

In contrast, in the semiconductor device 1, the channel 32 is formed at an interface (the interface between the diffusion region 12 and the insulating portion 4) that is different from the interface between the diffusion region 12 and the Schottky electrode 11. This makes it possible to achieve both an improvement in the Schottky barrier and a reduction in the source contact resistance.

In the semiconductor device 1 according to an embodiment, the diffusion region 12 is in contact with the two Schottky electrodes 11, and thus the contact area with the Schottky electrodes 11 is large. This can reduce the source contact resistance. Further, pitch shrink can be achieved more easily than in the semiconductor device 100 while maintaining a low source contact resistance. For example, the semiconductor device 1 can have a narrower pitch of the semiconductor elements 2 by about 10 times the corresponding pitch in the semiconductor device 100 of the comparative example.

### Method for Manufacturing Semiconductor Device 1

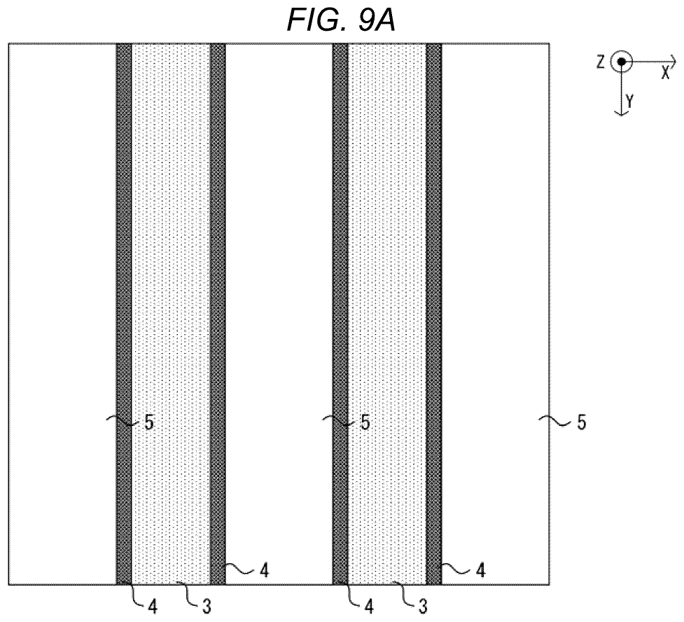

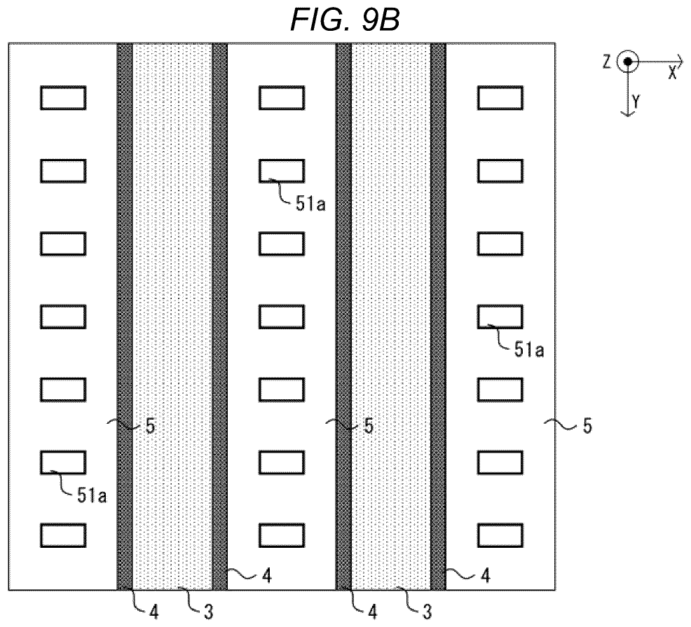

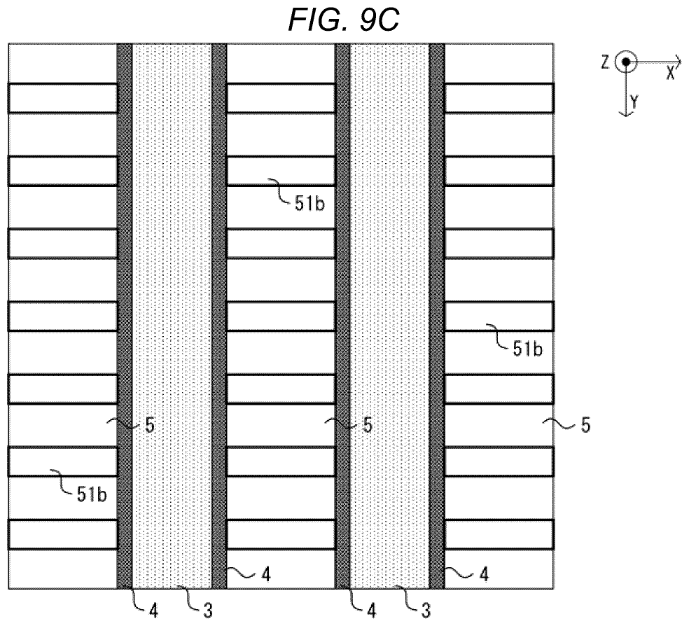

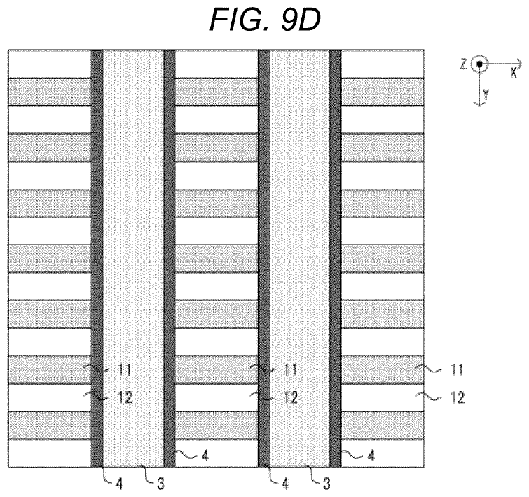

Next, an example of a method for manufacturing a semiconductor device 1 will be described. FIGS. 9A to 9D are views illustrating a manufacturing process of the semiconductor device 1 according to an embodiment of the present disclosure.

FIG. 9A is a view depicting a step of forming an interlayer film (insulating portion 4). In this step, the control electrode 3 and the insulating portion 4 (as an interlayer film of the semiconductor element 2) are formed. For example, a trench is formed by etching or the like from one main surface of the semiconductor layer 5, and an insulating material is formed so as to cover a side wall of the trench. The control electrode 3 is then formed in the insulating material. Thereafter, additional insulating material is formed so as to bury or embed the control electrode 3 within the trench, and the insulating portion 4 is thus completely formed. A plurality of control electrodes 3 are formed so as to be spaced from each other in the X-axis direction.

FIG. 9B is a view showing aspects related to a process of forming a trench contact. In this step, a plurality of trenches 51a (for embedding the Schottky electrodes 11) are formed in the semiconducting layer 5. The trenches 51a are formed in a dotted shape between adjacent control electrodes 3 so as to be arranged along the Y-axis direction. The trenches 51a can be formed by a photo engraving process (PEP) method, a reactive ion etching (RIE) method, or the like.

FIG. 9C is a view showing aspects related to an etching process of a trench contact. In this step, the side walls of the previously formed trenches 51a are etched by CDE (Chemical Dry Etching) or the like with a high selectivity ratio (SiO₂/Si), and the thus trenches 51b with a wider dimension are formed. Each trench 51b is formed so the ends reach the adjacent insulating portions 4.

FIG. 9D is a view showing a film forming process for a Schottky metal. In this step, the Schottky electrodes 11 are formed by depositing a metallic material in the previously formed trenches 51b. In this step, the electrode 7 may be continuously formed integrally with the Schottky electrode 11. Alternatively, the electrode 7 may be formed after this step.

In the back-end process of FIG. 9D or in the front-end process of any of FIG. 9A to FIG. 9D, an impurity can be implanted from one main surface side of the semiconductive layer 5, and the diffusion region 12 can be formed by a thermal diffusion process or the like. The thermal diffusion step may be performed as a separate step.

The Schottky electrodes 11, the diffusion regions 12, and the like shown in FIG. 1 can be formed by the processes shown by FIGS. 9A to 9D. According to the present embodiment, even if the formation position of the Schottky electrodes 11 is slightly shifted, the characteristics of the semiconductor element are not greatly affected, as compared with the comparative example described above.

In the described manufacturing process, even if the widths of the trenches 51a vary somewhat in the processing associated with FIG. 9B, the widths W of the Schottky electrodes 11 can still be uniform after the etching process associated with FIG. 9C. In particular, in a CDE process associated with FIG. 9C, the etching rate ratio of silicon (Si) of the semiconductor layer 5 can be substantially higher than that of the oxide film (SiO₂) of the insulating portion 4, and the insulating portion 4 may thus function as an etching stopper. Therefore, even if the widths of the trench 51a vary initially, the ultimate widths of the trench 51b can be made uniform. Therefore, the width W of each Schottky electrode 11 can be made uniform. Therefore, an alignment margin can be secured in the etching process associated with the FIG. 9C.

As described above, the semiconductor device 1 can have improved flexibility in selecting the thicknesses T of the diffusion regions 12 shown in the FIG. 4A and the like. That is, the degree of freedom in the formation interval between the Schottky electrodes 11 adjacent to each other in the Y-axis direction can be increased. Therefore, the manufacturing process of the semiconductor element 2 can be simplified.

As described above, the semiconductor device 1 includes the diffusion region 12 sandwiched between adjacent Schottky electrodes 11. In the diffusion region 12, when the semiconductor element 2 switches to an ON state, the channel 32 is formed on the boundary surface that is not facing the boundary surface in contact with the Schottky electrode 11. The channel 32 is not formed on the entire surface of the diffusion region 12 in the X-axis direction. This can reduce the on-resistance of the semiconductor device 1. Further, the speed of the off operation of the semiconductor device 1 can be increased.

Furthermore, the diffusion region 12 is in contact with the two Schottky electrodes 11, and therefore the contact area with the Schottky electrodes 11 is large. This can reduce source contact resistance. Further, the semiconductor device 1 can realize a low source contact resistance even when the pitch is narrowed. That is, the semiconductor device 1 can realize miniaturization and reduction in source contact resistance.

In the manufacturing process of the semiconductor device 1, a trench contact in which the Schottky electrode 11 is to be embedded is formed, and then the side walls of the trench contact are etched. The etching process of the side wall can provide an alignment margin for the final width of the trench contact for the Schottky electrode 11. This can simplify the manufacturing process.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first electrode;
a second electrode separated from the first electrode in a first direction;
a plurality of control electrodes between the first electrode and the second electrode, each control electrode extending in a second direction intersecting the first direction and spaced from each other in a third direction intersecting the first and second directions;
a semiconductor layer between the first electrode and the second electrode and having a first semiconductor region in ohmic contact with the first electrode;
a plurality of insulating portions in the semiconductor layer between the semiconductor layer and each control electrode;
a plurality of third electrodes between adjacent control electrodes of the plurality of control electrode in the third direction and spaced from each other third electrode in the second direction, each third electrode being sandwiched between adjacent insulating portions in the third direction and electrically connected to the second electrode; and
a second semiconductor region on the first semiconductor region in the semiconductor layer, the second semiconductor region having an impurity concentration higher than that of the first semiconductor region and being between adjacent third electrodes of the plurality of third electrodes in the second direction, the second semiconductor region being in Schottky contact with the adjacent third electrodes and having a width along the third direction that is greater than its width along the second direction.

2. The semiconductor device according to claim 1, wherein, in an ON state of the semiconductor device, each control electrode forms a channel region in the second semiconductor region at an interface of an insulating portion and a third electrode.

3. The semiconductor device according to claim 2, wherein the channel region does not form in other regions of the second semiconductor region.

4. The semiconductor device according to claim 1, wherein, in an OFF state of the semiconductor device, a depletion layer is formed in the second semiconductor region, the depletion layer extending from one insulating portion to an adjacent insulating portion.

5. The semiconductor device according to claim 4, wherein, a change of the semiconductor device from the OFF state to an ON state causes the depletion layer to shrink along the third direction.

6. The semiconductor device according to claim 1, wherein the second semiconductor region has a width along the second direction that is less than or equal to half its width along the third direction.

7. The semiconductor device according to claim 1, wherein
a dimension of the second semiconductor region along the second direction is not less than 50 nm but not more than 100 nm, and
a dimension of the second semiconductor region along the third direction is not less than 100 nm but not more than 200 nm.

8. The semiconductor device according to claim 1, further comprising;
a field plate electrode between each control electrode and the first electrode, the field plate electrode being electrically connected to the second electrode.

9. A semiconductor device, comprising:
a first electrode;
a second electrode separated from the first electrode in a first direction;
a first and a second control electrode between the first electrode and the second electrode in the first direction, the first and second control electrodes extending in parallel along a second direction intersecting the first direction and spaced from each other in a third direction intersecting the first and second directions;
a semiconductor layer between the first electrode and the second electrode in the first direction and having a first semiconductor region in ohmic contact with the first electrode;
a plurality of third electrodes between the first and second control electrodes in the third direction and spaced from each other in the second direction, each third electrode being electrically connected to the second electrode;
a second semiconductor region on the first semiconductor region in the semiconductor layer, the second semiconductor region having an impurity concentration higher than that of the first semiconductor region and being adjacent third electrodes of the plurality of third electrodes in the second direction, the second semiconductor region being in Schottky contact with the adjacent third electrodes, wherein
the first and second control electrodes are separated from the first semiconductor region, the second semiconductor region, and the plurality of third electrodes by insulating portions.

10. The semiconductor device according to claim 9, further comprising:
a conductive portion between the first control electrode and the first electrode, the conductive portion being electrically connected to the second electrode.

11. The semiconductor device according to claim 10, wherein, in an ON state of the semiconductor device, each of the first and second control electrodes forms a channel region in the second semiconductor region at an interface of an insulating portion and a third electrode.

12. The semiconductor device according to claim 11, wherein the channel region does not form in other regions of the second semiconductor region.

13. The semiconductor device according to claim 10, wherein, in an OFF state of the semiconductor device, a depletion layer is formed in the second semiconductor region, the depletion layer extending from one insulating portion to an adjacent insulating portion.

14. The semiconductor device according to claim 9, wherein the second semiconductor region has a width along the second direction that is less than or equal to half its width along the third direction.

15. The semiconductor device according to claim 9, wherein
a dimension of the second semiconductor region along the second direction is not less than 50 nm but not more than 100 nm, and
a dimension of the second semiconductor region along the third direction is not less than 100 nm but not more than 200 nm.

16. The semiconductor device according to claim 9, wherein the first and second control electrodes comprise polysilicon.

17. The semiconductor device according to claim 9, wherein a distance from a lowermost end of the first control electrode to the first electrode along the first direction is less than a distance along the first direction from the first electrode to a lowermost end of at least one third electrode in the plurality of third electrodes.

18. A method of manufacturing a semiconductor device, the method comprising: forming control electrodes in a semiconductor layer, the control electrodes being in insulation portions which extend in a first direction into the semiconductor layer and in a second direction substantially parallel to the semiconductor layer, the control electrodes being spaced from each other in a third direction intersecting the first direction and the second direction;
forming a plurality of trench contacts in the semiconductor layer in an area between the control electrodes, the trench contacts being spaced from each other along the second direction;
removing portions of the semiconductor layer until side walls of the plurality of trench contacts reach the insulating portions of adjacent control electrodes; and
forming a plurality of third electrodes in the plurality of trench contacts, each third electrode being in Schottky contact with the semiconductor layer.

19. The method of manufacturing the semiconductor device according to claim 18, wherein;
a distance between adjacent third electrodes along the second direction is less than a distance between insulating portions for adjacent control electrodes in the third direction.
